(19) United States
(12) Patent Application Publication
(10) Pub. No.: US 2008/0067551 A1
(43) Pub. Date: Mar. 20, 2008

(54) Semiconductor device having pseudo power supply wiring and method of designing the same

(75) Inventors: Yoshiro Riho, Tokyo (JP); Ken Ota, Tokyo (JP); Hiromasa Noda, Tokyo (JP); Shinichi Miyatake, Tokyo (JP)

Correspondence Address: FOLEY AND LARDNER LLP;SUITE 500, 3000 K STREET NW, WASHINGTON, DC, 20007, US

(73) Assignee: Elpida Memory, Inc.

(21) Appl. No.: 11/898,155

(22) Filed: Sep. 10, 2007

(30) Foreign Application Priority Data
Sep. 15, 2006 (JP) 2006-250620

(51) Int. Cl. H01L 27/105; G06F 17/50

(52) U.S. Cl. 257/207; 716/13; 257/E27.081

(57) ABSTRACT

Inverters are connected between a pseudo power supply wiring and a main power supply wiring, while inverters are connected between a main power supply wiring VDD and a pseudo power supply wiring. Connected to the sources of transistors are switching areas for switching to the main power supply wiring or the pseudo power supply wiring. Connected to the sources of transistors are switching areas for switching to the main power supply wiring or the pseudo power supply wiring. Even if improper connections are found or logical changes are required, the connection destination of the source is switched easily.

### TECHNICAL FIELD

The present invention relates to a semiconductor device and a method of designing the same, and, more particularly to a semiconductor device that has a pseudo power supply wiring for reducing standby power consumption and a method of designing the same.

### BACKGROUND OF THE INVENTION

In recent years, an operating voltage of a semiconductor device is gradually decreasing for the purposes of reducing consumption power, and at present, a very low voltage of as low as 1 bolt is sometimes used. When the operating voltage decreases, a threshold voltage of a transistor needs to be decreased. Thus, there occurs a problem in that a sub-threshold current of a transistor in an off state increases. To solve such a problem, a method of dividing a power supply wiring into a main power supply wiring and a pseudo power supply wiring is proposed in Japanese Patent Application Laid-open Nos. 2000-13215 and 2000-48568.

FIG. 10 is a circuit diagram of a general semiconductor device using a pseudo power supply wiring.

A circuit shown in FIG. 10 includes a circuit block 10 formed of 4-stage inverters 11 to 14. In the circuit block 10, a logic value is fixed in a standby state, and in this example, its input signal IN is fixed to a high level in the standby state. Needless to say, in an active state, a logical value of the input signal IN varies as needed.

In the circuit shown in FIG. 10, four power supply wirings, that is, a main power supply wiring VDD and a pseudo power supply wiring VDDZ to which a power supply potential is supplied; and a main power supply wiring VSS and a pseudo power supply wiring VSSZ to which a ground potential is supplied are arranged. Between the main power supply wiring VDD and the pseudo power supply wiring VDDZ, a N-channel MOS transistor 21 is arranged, and its gate electrode is supplied with a standby signal STT. Between the main power supply wiring VSS and the pseudo power supply wiring VSSZ, an P-channel MOS transistor 22 is arranged, and its gate electrode is supplied with a standby signal STB.

The standby signal STT becomes a low level when the circuit block 10 is rendered the standby state, and remains a high level when the circuit block 10 is in the active state. Thus, in the active state, the main power supply wiring VDD and the pseudo power supply wiring VDDZ are short-circuited via the transistor 21. On the other hand, in the standby state, the transistor 21 is kept in an off state. Thus, the pseudo power supply wiring VDDZ is disconnected from the main power supply wiring VDD, and as a result, nearly no power supply potential is supplied.

The standby signal STB is an inverted signal of the standby signal STT. The standby signal STB becomes a high level when the circuit block 10 is rendered the standby state, and remains a low level when the circuit block 10 is in the active state. Thus, in the active state, the main power supply wiring VSS and the pseudo power supply wiring VSSZ are short-circuited via the transistor 22. On the other hand, in the standby state, the transistor 22 is kept in an off state. Thus, the pseudo power supply wiring VSSZ is disconnected from the main power supply wiring VSS, and as a result, nearly no power supply potential is supplied.

Out of the four inverters 11 to 14 included in the circuit block 10, the first-stage inverter 11 and the third-stage inverter 13 are connected between the pseudo power supply wiring VDDZ and the main power supply wiring VSS, and the second-stage inverter 11 and the fourth-stage inverter 13 are connected between the main power supply wiring VDD and the pseudo power supply wiring VSSZ. As described above, in the active state, the main power supply wiring VDD and the pseudo power supply wiring VDDZ are short-circuited, and the main power supply wiring VSS and the pseudo power supply wiring VSSZ are short-circuited. Thus, a power supply voltage is correctly applied to both power supply terminals of all the inverters 11 to 14. As a result, the circuit block 10 can operate correctly, and an output signal OUT of the circuit block 10 is rendered a correct value according to a logical value of the input signal IN.

On the contrary, in the standby state, the pseudo power supply wiring VDDZ is disconnected from the main power supply wiring VDD, and the pseudo power supply wiring VSSZ is disconnected from the main power supply wiring VSS. Thus, sources of P-channel MOS transistors 11p and 13p included in the first-stage inverter 11 and the third-stage inverter 13 are supplied with nearly no power supply potential, and sources of N-channel MOS transistors 12n and 14n included in the second-stage inverter 12 and the fourth-stage inverter 14 are supplied with nearly no power supply potential.

However, in the standby state, the input signal IN is fixed to the high level. The transistors rendered conducting in the respective inverters 11 to 14 are fixed to an N-channel MOS transistor 11n, a P-channel MOS transistor 12p, an N-channel MOS transistor 13n, and a P-channel MOS transistor 14p shown in FIG. 10, respectively. Sources of these transistors are connected to the main power supply wiring VDD or the main power supply wiring VSS, and thus, the logic value in the standby state is kept correctly.

On the other hand, sources of the P-channel MOS transistors 11p and 13p rendered non-conducting in the standby state are connected to the pseudo power supply wiring VDDZ disconnected from the main power supply wiring VDD. As a result, nearly no sub-threshold current is passed. Likewise, sources of the N-channel MOS transistors 12n and 14n rendered non-conducting in the standby state are connected to the pseudo power supply wiring VSSZ disconnected from the main power supply wiring VSS. As a result, nearly no sub-threshold current is passed. Thereby, it becomes possible to reduce the power consumption in the standby state of the circuit block 10.

As described above, it is effective to divide power supply wirings into the main power supply wiring and the pseudo power supply wiring in the circuit block whose logic is fixed at the time of standby state. Standby power consumption is reduced significantly.

However, if the logic of the circuit block is complicated, verification of the logic fixed at the time of standby state is also complicated. Namely, determination as to whether the source of the transistor that constitutes the circuit block is connected to the main power supply wiring or the pseudo power supply wiring is difficult. If the source of the transistor is connected to the pseudo power supply wiring by mistake instead of the main power supply wiring, the logic may be unstable at the time of standby state and leak current from circuits on the subsequent stages may be increased.

If such an improper connection is found, a mask for using a photolithography process must be modified at the time of designing. In some layouts, modification must be performed to a large degree upon not only the region where the improper connection is found but also the peripheral region, which takes a prolonged period of time. If logical changes are required, modification is performed extensively.

### SUMMARY OF THE INVENTION

Therefore, an object of the present invention is to provide a semiconductor device that enables easy switching of source of a transistor from a main power supply wiring to a pseudo power supply wiring or vice versa in response to an improper connection to power source and a logical change, and a method of designing the same.

A semiconductor device according to the present invention comprising:

a main power supply wiring;

a pseudo power supply wiring which is connected to the main power supply wiring in an active state and disconnected from the main power supply wiring in a standby state;

a transistor whose source is connected to one of the main power supply wiring and the pseudo power supply wiring;

a drawing conductor connected to the source of the transistor;

a through-hole conductor whose one end is connected to the drawing conductor and whose other end is led between the main power supply wiring and the pseudo power supply wiring; and

a power connection conductor for connecting the other end of the through-hole conductor to one of the main power supply wiring and the pseudo power supply wiring.

A method of designing a semiconductor device according to the present invention that includes a main power supply wiring, a pseudo power supply wiring which is connected to the main power supply wiring in an active state and disconnected from the main power supply wiring in a standby state, and a transistor whose source is connected to one of the main power supply wiring and the pseudo power supply wiring, comprising the steps of:

laying out the main power supply wiring and the pseudo power supply wiring that are parallel with each other on the same wiring layer;

laying out a power connection conductor connected to the source of the transistor between the main power supply wiring and the pseudo power supply wiring; and

connecting the power connection conductor to one of the main power supply wiring and the pseudo power supply wiring by extending the power connection conductor toward one of the main power supply wiring and the pseudo power supply wiring.

According to the present invention, a power connection conductor connected to the source of a transistor is laid out between a main power supply wiring and a pseudo power supply wiring. If the power connection conductor is extended to the main power supply wiring so as to be connected to the same, the source of the transistor is connected to the main power supply wiring. If the power connection conductor is extended to the pseudo power supply wiring so as to be connected to the same, the source of the transistor is connected to the pseudo power supply wiring.

Because the connection destination of the source is switched easily even though improper connections are found or logical changes are required, a mask is modified easily at the time of design. The number of design processes including fabrication, selection, evaluation, and defect analysis of the mask and design cost can be reduced.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a circuit diagram conceptually showing characteristics of a semiconductor device according to a preferred embodiment of the present invention;

FIG. 2A is a schematic plan view of typical device configuration of a switching area;

FIG. 2B is a schematic cross-sectional view along the line A-A shown in FIG. 2A;

FIG. 3A is a schematic plan view of a typical device configuration at the time of connecting the switching area to the main power supply wiring VDD;

FIG. 3B is a schematic cross-sectional view along the line B-B shown in FIG. 3A;

FIG. 4A is a schematic plan view of a typical device configuration at the time of connecting the switching area to the pseudo power supply wiring VDDZ;

FIG. 4B is a schematic cross-sectional view along the line C-C shown in FIG. 4A;

FIG. 5 is a schematic plan view of a typical layout on the diffusion layer of the dependently connected two-stage inverter circuit;

FIG. 6 is a schematic plan view of a typical layout of a gate wiring layer formed on the diffusion layer shown in FIG. 5;

FIG. 7A shows the layout of a tungsten wiring layer placed on the upper layer of the gate wiring layer;

FIG. 7B shows the layout of an aluminum wiring layer placed on the upper layer of the tungsten wiring layer;

FIG. 8 is an example of a changed layout of the power connection conductors;

FIG. 9 is a typical plan view for explaining the preferred method of arranging transistors that constitute a circuit block; and

FIG. 10 is a circuit diagram of a general semiconductor device using a pseudo power supply wiring.

### DETAILED DESCRIPTION OF THE EMBODIMENTS

Preferred embodiments of the present invention will now be explained in detail with reference to the drawings.

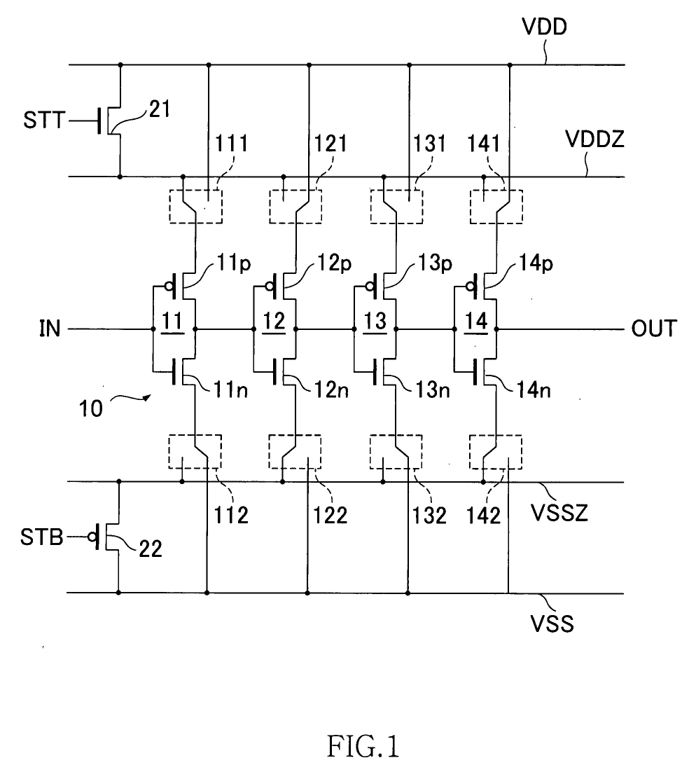

FIG. 1 is a circuit diagram conceptually showing characteristics of a semiconductor device according to a preferred embodiment of the present invention.

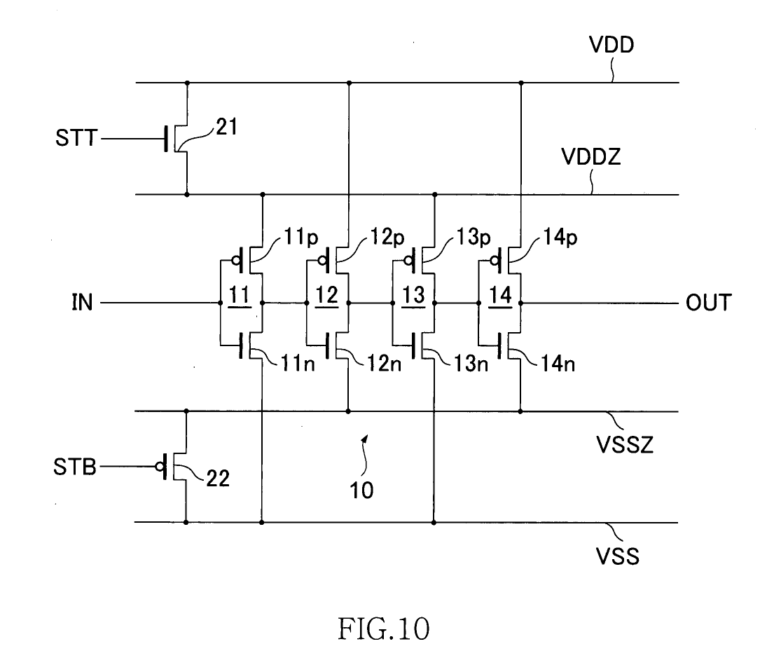

As shown in FIG. 1, the circuit configuration of the semiconductor device according to the present embodiment is the same as that of FIG. 10. Among four circuit inverters 11 to 14 included in the circuit block 10, the first inverter 11 and the third inverter 13 are connected between the pseudo power supply wiring VDDZ and the main power supply wiring VSS. The second inverter 12 and the fourth inverter 14 are connected between the main power supply wiring VDD and the pseudo power supply wiring VSSZ. The N-channel MOS transistor 21 is provided between the main power supply wiring VDD and the pseudo power supply wiring VDDZ and its gate electrode receives the standby signal STT. The P-channel MOS transistor 22 is provided between the main power supply wiring VSS and the pseudo power supply wiring VSSZ and its gate electrode receives the standby signal STB.

According to the semiconductor device of the present embodiment, the sources of the P-channel MOS transistors 11p to 14p are connected via switching areas 111, 121, 131, and 141 to the main power supply wiring VDD or the pseudo power supply wiring VDDZ. The sources of the N-channel MOS transistors 11n to 14n are connected via switching areas 112, 122, 132, and 142 to the main power supply wiring VSS or the pseudo power supply wiring VSSZ.

The switching areas 111, 121, 131, and 141 are circuit areas for connecting the sources of the transistors 11p to 14p to either the main power supply wiring VDD or the pseudo power supply wiring VDDZ. According to this example, the switching areas 111 and 131 are connected to the pseudo power supply wiring VDDZ, while the switching areas 121 and 141 are connected to the main power supply wiring VDD. Similarly, the switching areas 112, 122, 132, and 142 are circuit areas for connecting the sources of the transistors 11n to 14n to either the main power supply wiring VSS or the pseudo power supply wiring VSSZ. According to this example, the switching areas 112 and 132 are connected to the main power supply wiring VSS, while the switching areas 122 and 142 are connected to the pseudo power supply wiring VSSZ.

As described later, such a switching area is for switching connection in response to changes in mask at the time of designing, unlike a usual electronic switch that is a circuit which enables electrical switching after manufacturing a semiconductor device. Accordingly, after the semiconductor device is completed, the switching area cannot be utilized for changing the connection.

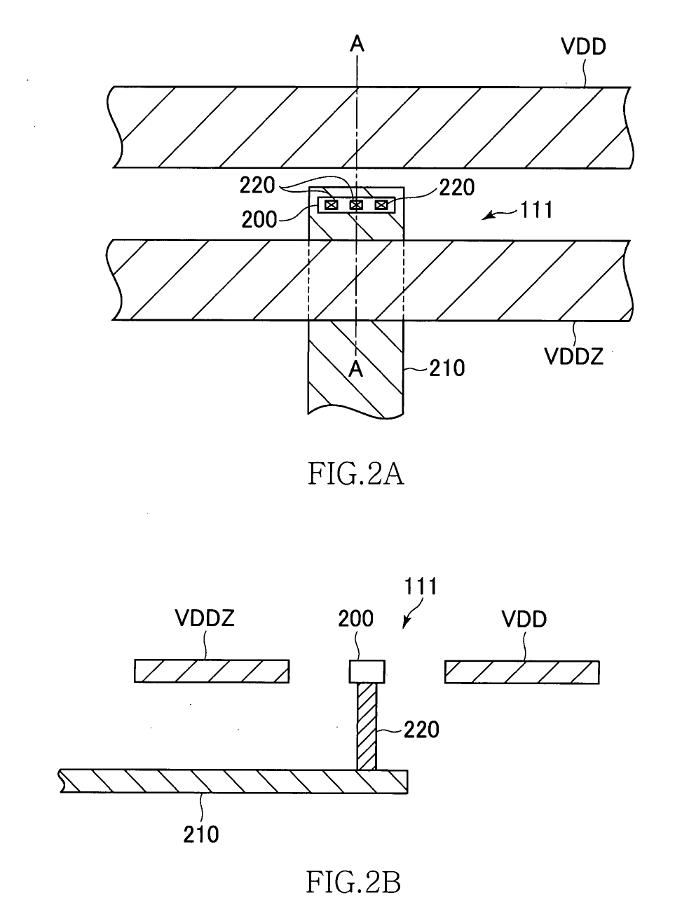

FIG. 2A is a schematic plan view of typical device configuration of the switching area 111. FIG. 2B is a schematic cross-sectional view along the line A-A shown in FIG. 2A. These drawings show not the actual device configuration, but the imaginary state before the source of the transistor 11p is connected to the main power supply wiring VDD or the pseudo power supply wiring VDDZ. The state before connection to the main power supply wiring VDD or the pseudo power supply wiring VDDZ in a mask design process is merely shown as the imaginary device configuration.

As shown FIGS. 2A and 2B, in the mask design process, the main power supply wiring VDD and the pseudo power supply wiring VDDZ are laid out on the same wiring layer so as to be parallel to each other. A power connection conductor 200 is placed between the main power supply wiring VDD and the pseudo power supply wiring VDDZ. The power connection conductor 200 is formed on the same wiring layer as the main power supply wiring VDD and the pseudo power supply wiring VDDZ and placed at a substantially intermediate portion between the main power supply wiring VDD and the pseudo power supply wiring VDDZ.

The power connection conductor 200 is connected via a plurality of through-hole conductors 220 to the underlying drawing conductor 210. The drawing conductor 210 is connected to the source of the transistor 11p. One end of the through-hole conductor 220 is connected to the drawing conductor 210, and the other end is led to the substantially intermediate portion between the main power supply wiring VDD and the pseudo power supply wiring VDDZ.

The device configurations of the switching areas 121, 131, and 141 are the same as in FIGS. 2A and 2B except that the drawing conductor 210 is connected to the sources of the transistors 12p to 14p. The switching areas 112, 122, 132, and 142 corresponding to the transistors 11n to 14n, respectively have the same configuration as in FIGS. 2A and 2B except that the drawing conductor 210 is connected to the sources of the transistors 11n to 14n and the main power supply wiring VSS and the pseudo power supply wiring VSSZ are utilized instead of the main power supply wiring VDD and the pseudo power supply wiring VDDZ.

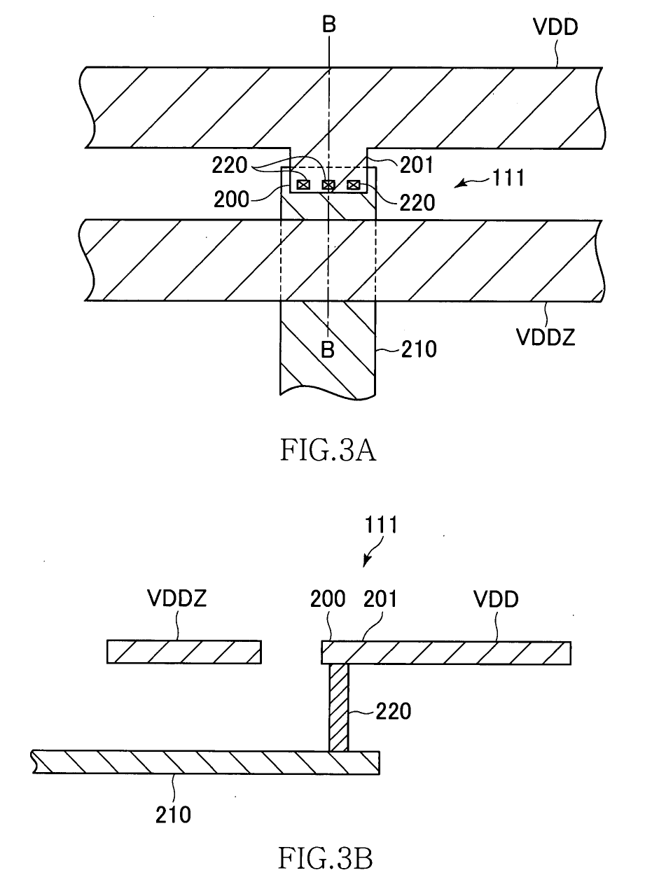

FIG. 3A is a schematic plan view of a typical device configuration at the time of connecting the switching area 111 to the main power supply wiring VDD. FIG. 3B is a schematic cross-sectional view along the line B-B shown in FIG. 3A.

As shown in FIGS. 3A and 3B, when the switching area 111 is connected to the main power supply wiring VDD, the power connection conductor 200 is extended to the main power supply wiring VDD so as to be connected to the same. In actual design, a rectangular conductor 201 is added between the power connection conductor 200 and the main power supply wiring VDD to short the power connection conductor 200 and the main power supply wiring VDD.

The source of the transistor 11p is thus connected via the drawing conductor 210, the through-hole conductor 220, and the power connection conductor 200 to the main power supply wiring VDD. When the switching areas 121, 131, and 141 are connected to the main power supply wiring VDD or the switching areas 112, 122, 132, and 142 are connected to the main power supply wiring VSS, as shown in FIGS. 3A and 3B, the power connection conductor 200 is extended to the main power supply wiring VDD or VSS.

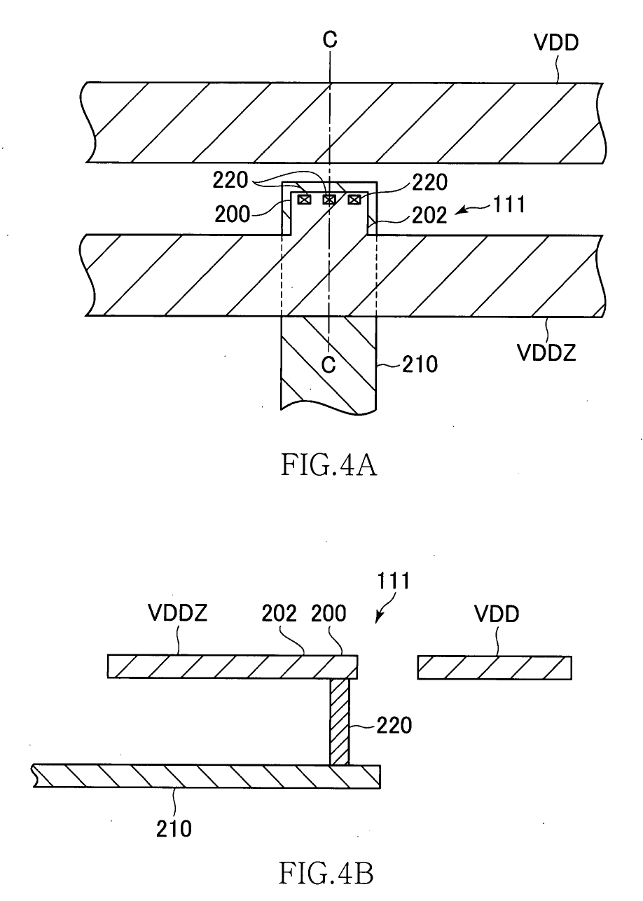

FIG. 4A is a schematic plan view of a typical device configuration at the time of connecting the switching area 111 to the pseudo power supply wiring VDDZ. FIG. 4B is a schematic cross-sectional view along the line C-C shown in FIG. 4A.

As shown in FIGS. 4A and 4B, when the switching area 111 is connected to the pseudo power supply wiring VDDZ, the power connection conductor 200 is extended to the pseudo power supply wiring VDDZ so as to be connected to the same. In actual design, a rectangular conductor 202 is added between the power connection conductor 200 and the pseudo power supply wiring VDDZ to short the power connection conductor 200 and the pseudo power supply wiring VDDZ.

The source of the transistor 11p is thus connected via the drawing conductor 210, the through-hole conductor 220, and the power connection conductor 200 to the pseudo power supply wiring VDDZ. When the switching areas 121, 131, and 141 are connected to the pseudo power supply wiring VDDZ or the switching areas 112, 122, 132, and 142 are connected to the pseudo power supply wiring VSSZ, as shown in FIGS. 4A and 4B, the power connection conductor 200 is extended to the pseudo power supply wiring VDDZ or VSSZ.

According to the switching area utilized in the present embodiment, the power connection conductor 200 is extended to either the main power supply wiring or the pseudo power supply wiring to connect the source of the transistor to either the main power supply wiring or the pseudo power supply wiring. If the source of the transistor is connected to one of the main power supply wiring and the pseudo power supply wiring and then connected to the other in response to design changes, a mask is modified remarkably easily. Switching of connection is completed merely by exchanging the rectangular conductor 201 for 202 on the mask. Other lines and through-holes do not need to be moved.

The configuration of the semiconductor device of the present embodiment will be described in detail by taking a dependently connected two-stage inverter circuit as an example.

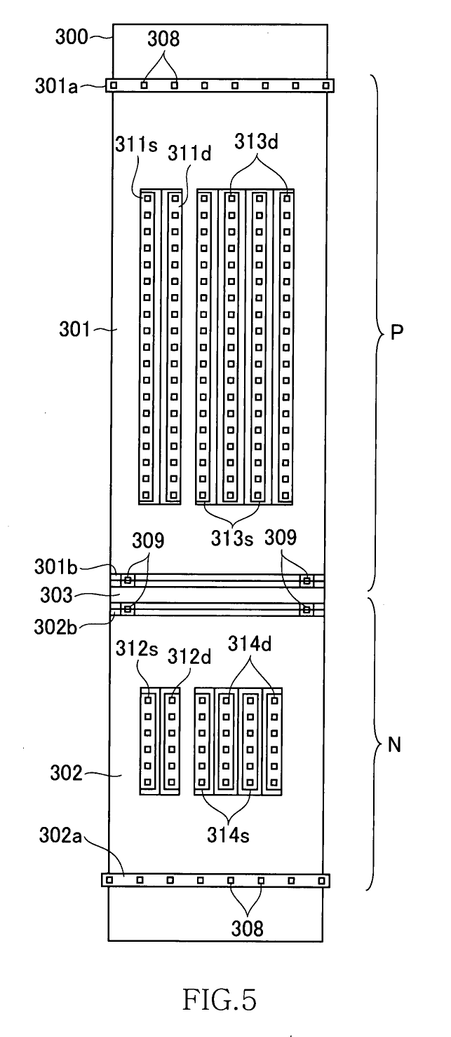

FIG. 5 is a schematic plan view of a typical layout on the diffusion layer of the dependently connected two-stage inverter circuit.

As shown in FIG. 5, a layout area 300 of the two-stage inverter circuit has a region P where P-channel MOS transistors are formed and a region N where N-channel MOS transistors are formed and these regions are separated by a device isolation region 303. As the result of consideration of the difference in capability between the P-channel MOS transistor and the N-channel MOS transistor, the region P is made to be larger than the region N.

The region P is provided with an N-well 301, the source region 311s and drain region 311d of the P-channel MOS transistor which constitutes the first inverter, and the source region 313s and drain region 313d of the P-channel MOS transistor which constitutes the second inverter. The second inverter has two source regions 313s and two drain regions 313d because its drive capability is designed to be larger than that of the first inverter. Well contact regions 301a and 301b with high impurity density are provided at the both ends of the N-well 301.

The region N is provided with a P-well 302, the source region 312s and drain region 312d of the N-channel MOS transistor which constitutes the first inverter, and the source region 314s and drain region 314d of the N-channel MOS transistor which constitutes the second inverter. Well contact regions 302a and 302b with high impurity density are provided at the both ends of the P-well 302.

In FIG. 5, a contact 308 in the well contact regions 301a and 302a and a contact 309 in the well contact regions 301b and 302b are for connecting an upper wiring layer to be described later to the well contact region. The base contacts are disposed so as to oppose with each other with the transistor interposed therebetween because the base potential is more stabilized by being supplied from the both ends of the transistor.

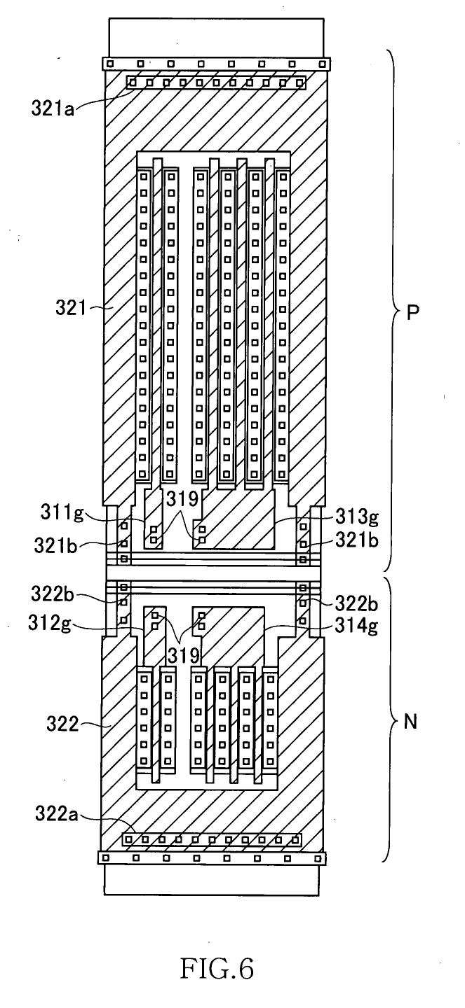

FIG. 6 is a schematic plan view of a typical layout of a gate wiring layer formed on the diffusion layer shown in FIG. 5.

As shown in FIG. 6, gate electrodes 311g to 314g and base connection conductors 321 and 322 are formed on the gate wiring layer. The gate electrodes 311g to 314g are provided between the corresponding source regions 311s to 314s and the corresponding drain regions 311d to 314d, respectively, so that four MOS transistors are formed. In FIG. 6, contacts 319 provided on the gate electrodes 311g to 314g are for connecting an upper wiring layer to be described later to the gate electrodes 311g to 314g.

The base connection conductor 321 is provided for supplying base potential to the base of the P-channel MOS transistor and made so as to surround the gate electrodes 311g and 313g on three sides. In FIG. 6, a contact 321a at the top of the base connection conductor 321 and a contact 321b at the bottom ends are for connecting an upper wiring layer to be described later to the base connection conductor 321.

The base connection conductor 322 is provided for supplying base potential to the base of the N-channel MOS transistor and made so as to surround the gate electrodes 312g and 314g on three sides. In FIG. 6, a contact 322a at the bottom of the base connection conductor 322 and a contact 322b at the top ends are for connecting the upper wiring layer to be described later to the base connection conductor 322.

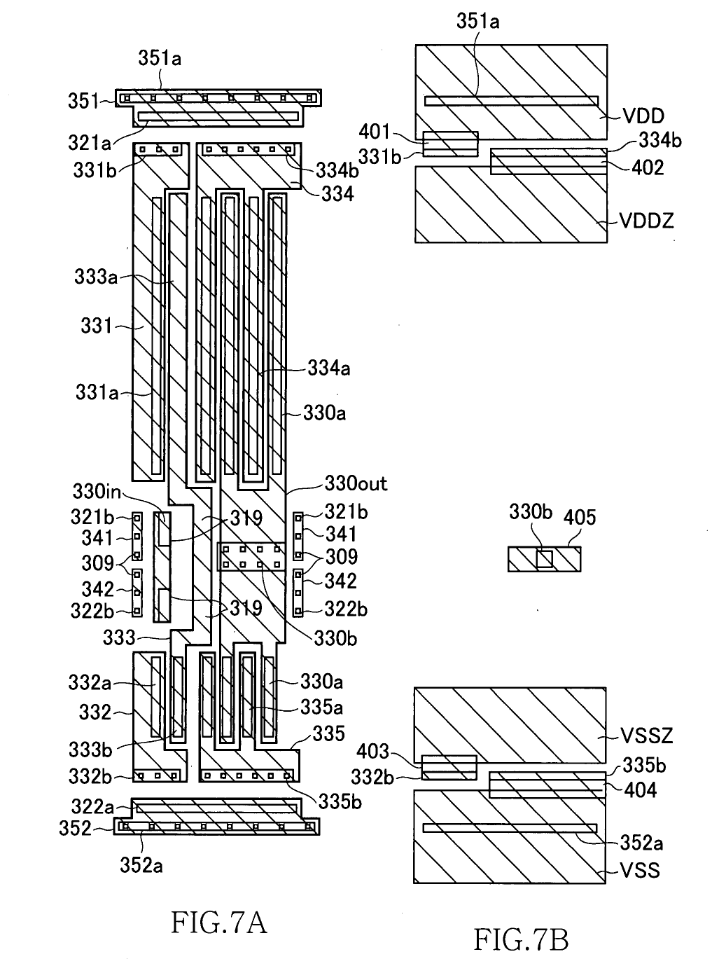

FIGS. 7A and 7B are schematic plan views of a typical layout of a metal wiring layer formed on the diffusion layer shown in FIG. 6. FIG. 7A shows the layout of a tungsten wiring layer placed on the upper layer of the gate wiring layer. FIG. 7B shows the layout of an aluminum wiring layer placed on the upper layer of the tungsten wiring layer. For clarity, the layout of the underlying wiring layer and diffusion layer is not shown in FIGS. 7A and 7B.

As shown in FIG. 7A, the tungsten wiring layer is provided with a conductor 330in to which an input signal is supplied and a conductor 330out to which an output signal is supplied. The conductor 330in is connected commonly via the contact 319 to the underlying gate electrodes 311g and 312g. The conductor 330out is connected commonly via a contact 330a to the drain regions 313d and 314d. The conductor 330out is connected via a contact 330b to the upper aluminum wiring layer from which the output signal is drawn.

The tungsten wiring layer is also provided with conductors 331 to 335. The conductor 331 is provided for supplying source potential to the P-channel MOS transistor which constitutes the first inverter. The conductor 331 is connected via a contact 331a to the source region 311s and via a contact 331b to the upper aluminum wiring layer. The conductor 332 is provided for supplying source potential to the N-channel MOS transistor which constitutes the first inverter. The conductor 332 is connected via a contact 332a to the source region 312s and via a contact 332b to the upper aluminum wiring layer.

The conductor 333 is connected via a contact 333a to the drain region 311d and via a contact 333b to the drain region 312d. The conductor 333 is further connected via the contact 319 to the underlying gate electrodes 313g and 314g so as to connect the first inverter to the second inverter.

The conductor 334 is provided for supplying source potential to the P-channel MOS transistor which constitutes the second inverter. The conductor 334 is connected via a contact 334a to the source region 313s and via a contact 334b to the upper aluminum wiring layer. The conductor 335 is provided for supplying source potential to the N-channel MOS transistor which constitutes the second inverter. The conductor 335 is connected via a contact 335a to the source region 314s and via a contact 335b to the upper aluminum wiring layer.

The tungsten wiring layer is further provided with conductors 341 and 342. The conductor 341 is connected via a contact 321b to the underlying base connection conductor 321 and via the contact 309 to the well contact region 301b. The base connection conductor 321 and the well contact region 301b are thus shorted via the conductor 341. Similarly, the conductor 342 is connected via a contact 322b to the underlying base connection conductor 322 and via the contact 309 to the well contact region 302b. The base connection conductor 322 and the well contact region 302b are thus shorted via the conductor 342.

The tungsten wiring layer is provided with conductors 351 and 352. The conductor 351 is connected via a contact 351a to the upper main power supply wiring VDD and the underlying well contact region 301a and via the contact 321a to the underlying base connection conductor 321. The well contact region 301a thus receives the potential of the main power supply wiring VDD via the conductor 351. The well contact region 301b also receives the potential of the main power supply wiring VDD via the conductor 351, the base connection conductor 321, and the conductor 341.

Similarly, the conductor 352 is connected via a contact 352a to the upper main power supply wiring VSS and the well contact region 302a and via the contact 322a to the underlying base connection conductor 322. The well contact region 302a thus receives the potential of the main power supply wiring VSS via the conductor 352. The well contact region 302b also receives the potential of the main power supply wiring VSS via the conductor 352, the base connection conductor 322, and the conductor 342.

According to the present embodiment, the well contact regions 301a and 301b are connected to the main power supply wiring VDD, while the well contact regions 302a and 302b are connected to the main power supply wiring VSS. Namely, the well contact regions 301a and 301b are not connected to the pseudo power supply wiring VDDZ. The well contact region 302a and 302b are not connected to the pseudo power supply wiring VSSZ. According to the semiconductor device of this embodiment, as shown in FIG. 1, the inverters are connected between the main power supply wiring and the pseudo power supply wiring. The base potentials of the transistors constituting the respective inverters are fixed to the potential of the main power supply wiring.

As shown in FIG. 7B, the aluminum wiring layer is provided with the main power supply wiring VDD, the pseudo power supply wiring VDDZ, the main power supply wiring VSS, and the pseudo power supply wiring VSSZ. The contacts 331b and 334b are provided between the main power supply wiring VDD and the pseudo power supply wiring VDDZ. An end of the through-hole conductor placed between the main power supply wiring VDD and the pseudo power supply wiring VDDZ is led therebetween. The contact 331b is connected via a power connection conductor 401 to the main power supply wiring VDD. The contact 334b is connected via a power connection conductor 402 to the pseudo power supply wiring VDDZ. The underlying conductor 331 is thus connected to the main power supply wiring VDD, while the underlying conductor 334 is connected to the pseudo power supply wiring VDDZ.

Similarly, the contacts 332b and 335b are provided between the main power supply wiring VSS and the pseudo power supply wiring VSSZ. An end of the through-hole conductor placed between the main power supply wiring VSS and the pseudo power supply wiring VSSZ is led therebetween. The contact 332b is connected via a power connection conductor 403 to the pseudo power supply wiring VSSZ, while the contact 335b is connected via a power connection conductor 404 to the main power supply wiring VSS. The underlying conductor 332 is connected to the pseudo power supply wiring VSSZ, while the underlying conductor 335 is connected to the main power supply wiring VSS.

The aluminum wiring layer is further provided with a conductor 405 which is connected via the contact 330b to the conductor 330out. The conductor 405 is further connected via a contact (not shown) to an upper metal wiring layer from which the output signal is drawn.

As the result of the above-described configuration, the two-stage inverter circuit is made on the layout area 300 shown in FIG. 5. The source of the P-channel MOS transistor which constitutes the first inverter is connected to the main power supply wiring VDD, and the source of the N-channel MOS transistor is connected to the pseudo power supply wiring VSSZ. The source of the P-channel MOS transistor which constitutes the second inverter is connected to the pseudo power supply wiring VDDZ, and the source of the N-channel MOS transistor is connected to the main power supply wiring VSS.

Whether the sources of the transistors are connected to the main power supply wiring or the pseudo power supply wiring is determined only by the layout of the power connection conductors 401 to 404 placed between the main power supply wiring and the pseudo power supply wiring. If the source of the transistor is switched from the main power supply wiring to the pseudo power supply wiring or vice versa in response to an improper connection to the power source or a logical change, the positions of the power connection conductors 401 to 404 on the mask are merely changed. Other elements do not need to be changed.

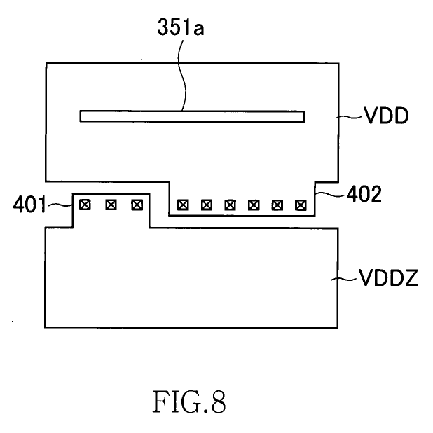

FIG. 8 is an example of a changed layout of the power connection conductors 401 and 402.

As shown in FIG. 8, the power connection conductor 401 is moved downward in the figure, so that the contact 331b is connected to the pseudo power supply wiring VDDZ. The power connection conductor 402 is moved upward in the figure, so that the contact 334b is connected to the main power supply wiring VDD. The opposite connection to that of FIG. 7B is thus obtained.

According to the semiconductor device of the present embodiment, the base is connected to the main power supply wiring in a fixed manner regardless of whether the source of the transistor is connected to the main power supply wiring or the pseudo power supply wiring. Even if the source of the transistor is switched from the main power supply wiring to the pseudo power supply wiring or vice versa, connections to the base do not need to be changed.

Because the base of the transistor is shorted with the source in usual designs, conductors for shorting directly the base and the source are usually provided. According to the present embodiment, however, the source is configured to be connected to both the main power supply wiring and the pseudo power supply wiring, and connection destinations are changed easily. In view of that, the base must be connected to the main power supply wiring. In order to realize that, the conductor for shorting the base and the source of the transistor directly is not required. Instead, by utilizing the base potential supplying conductor, the main power supply wiring is connected to the base of the transistor. Because the gate electrode layer is utilized for the base potential supplying conductor as described above, the area is not increased and the number of wiring layers is not increased, either.

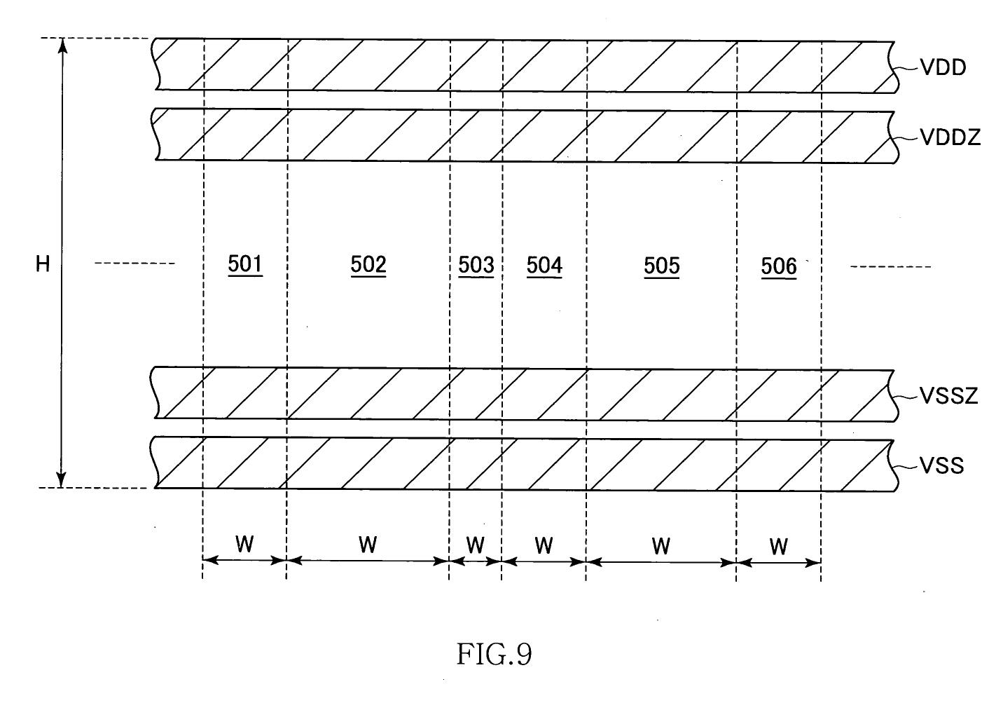

FIG. 9 is a typical plan view for explaining the preferred method of arranging transistors that constitute a circuit block.

According to the preferred arrangement method, as shown in FIG. 9, the main power supply wiring VDD, the pseudo power supply wiring VDDZ, the main power supply wiring VSS, and the pseudo power supply wiring VSSZ are laid out straight in a direction. Layout areas 501, 502, 503, . . . where the transistors are formed are arranged in the elongated area formed by these lines along the longitudinal direction. Examples of the circuit formed in the layout area include the circuit which utilizes the pseudo power supply wiring VDDZ or VSSZ, the circuit which utilizes only the main power supply wiring VDD, VSS, and the transistors 21 and 22 shown in FIG. 1.

As shown in FIG. 9, the widths W of the layout areas are varied depending on differences in size of transistors and in circuit configuration. Because the power supply wirings are laid out straight in a direction, the heights H of the layout areas are the same.

According to usual design methods, the heights of the layout areas are adjusted depending on whether the source of the transistor is connected to the main power supply wiring or the pseudo power supply wiring, and the main power supply wiring and the pseudo power supply wiring are partially wound correspondingly. According to such a layout, however, if the source of the transistor is switched from the main power supply wiring to the pseudo power supply wiring or vice versa, other layout areas may be greatly affected. A mask is thus modified extensively.

As shown in FIG. 9, if the main power supply wiring VDD, the pseudo power supply wiring VDDZ, the main power supply wiring VSS, and the pseudo power supply wiring VSSZ are laid out straight in a direction, other layout areas are not affected at all even though the aforementioned switching is required. The mask is thus modified remarkably easily.

The present invention is in no way limited to the aforementioned embodiments, but rather various modifications are possible within the scope of the invention as recited in the claims, and naturally these modifications are included within the scope of the invention.

What is claimed is:

1. A semiconductor device comprising:
a main power supply wiring;
a pseudo power supply wiring which is connected to the main power supply wiring in an active state and disconnected from the main power supply wiring in a standby state;
a transistor whose source is connected to one of the main power supply wiring and the pseudo power supply wiring;
a drawing conductor connected to the source of the transistor;
a through-hole conductor whose one end is connected to the drawing conductor and whose other end is led between the main power supply wiring and the pseudo power supply wiring; and
a power connection conductor for connecting the other end of the through-hole conductor to one of the main power supply wiring and the pseudo power supply wiring.

2. The semiconductor device as claimed in claim 1, wherein the other end of the through-hole conductor is placed at a substantially intermediate portion between the main power supply wiring and the pseudo power supply wiring.

3. The semiconductor device as claimed in claim 1, wherein the main power supply wiring, the pseudo power supply wiring, and the power connection conductor are formed on the same wiring layer.

4. The semiconductor device as claimed in claim 1 further comprising a base potential supplying conductor for connecting a base of the transistor whose source is connected to the pseudo power supply wiring to the main power supply wiring.

5. The semiconductor device as claimed in claim 4, wherein at least a part of the base potential supplying conductor is formed on the same wiring layer as the gate electrode of the transistor.

6. The semiconductor device as claimed in claim 5, wherein the base of the transistor is connected via a first contact under the main power supply wiring to the main power supply wiring, and via a second contact placed on a side of the base potential supplying conductor or on the opposite side of the first contact seen from the transistor, to the main power supply wiring.

7. The semiconductor device as claimed in claim 1, wherein a plurality of transistors are arranged in a direction, and the main power supply wiring and the pseudo power supply wiring are formed straight along the direction.

8. A semiconductor device comprising:
a main power supply wiring;
a pseudo power supply wiring which is connected to the main power supply wiring in an active state and disconnected from the main power supply wiring in a standby state; and
a plurality of transistors whose sources are connected to one of the main power supply wiring and the pseudo power supply wiring, wherein
among the plurality of transistors, both a base of a transistor whose source is connected to the main power supply wiring and a base of a transistor whose source is connected to the pseudo power supply wiring are connected to the main power supply wiring.

9. The semiconductor device as claimed in claim 8, wherein the base of the transistor is connected via a first contact under the main power supply wiring to the main power supply wiring, and via a second contact placed on a side of a base potential supplying conductor provided on the same wiring layer as a gate electrode of the transistor or on the opposite side of the first contact seen from the transistor, to the main power supply wiring.

10. The semiconductor device as claimed in claim 8, wherein a plurality of transistors are arranged in a direction, and the main power supply wiring and the pseudo power supply wiring are formed straight along the direction.

11. A method of designing a semiconductor device that includes a main power supply wiring, a pseudo power supply wiring which is connected to the main power supply wiring in an active state and disconnected from the main power supply wiring in a standby state, and a transistor whose source is connected to one of the main power supply wiring and the pseudo power supply wiring, comprising the steps of:
laying out the main power supply wiring and the pseudo power supply wiring that are parallel with each other on the same wiring layer;
laying out a power connection conductor connected to the source of the transistor between the main power supply wiring and the pseudo power supply wiring; and
connecting the power connection conductor to one of the main power supply wiring and the pseudo power supply wiring by extending the power connection conductor toward one of the main power supply wiring and the pseudo power supply wiring.

12. The method of designing a semiconductor device as claimed in claim 11, wherein at a time of design change, the power connection conductor connected to one of the main power supply wiring and the pseudo power supply wiring is extended toward the other of the main power supply wiring and the pseudo power supply wiring so as to be connected to the other of the main power supply wiring and the pseudo power supply wiring.
